(19) United States
(12) Patent Application Publication
(10) Pub. No.: US 2010/0024865 A1
(43) Pub. Date: Feb. 4, 2010

(54) CONTINUOUS COATING INSTALLATION, METHODS FOR PRODUCING CRYSTALLINE SOLAR CELLS, AND SOLAR CELL

(75) Inventors: Arvind Shah, Berax (CH); Horst Schade, Deisenhofen (DE); Holger Muenz, Aalen (DE); Martin Voelcker, Koenigsbronn (DE); Michael Schall, Essingen (DE); Matthias Krantz, Altenholz (DE)

Correspondence Address: FISH & RICHARDSON PC, P.O. BOX 1022, MINNEAPOLIS, MN, 55440-1022, US

(73) Assignees: CARL ZEISS LASER OPTICS GMBH, Oberkochen (DE); CARL ZEISS SMT AG, Oberkochen (DE)

(21) Appl. No.: 12/538,998

(22) Filed: Aug. 11, 2009

Related U.S. Application Data
(63) Continuation of application No. PCT/EP2008/001465, filed on Feb. 25, 2008.
(60) Provisional application No. 60/903,739, filed on Feb. 27, 2007.

(51) Int. Cl. H01L 31/0376; H01L 21/20; C23C 14/34

(52) U.S. Cl. 136/244; 438/487; 204/298.23; 204/298.03; 257/E21.134

(57) ABSTRACT

A continuous coating installation is disclosed. The installation includes a vacuum chamber having a supply opening for supplying a substrate to be coated and a discharge opening for discharging the coated substrate. The installation also includes a physical vapour deposition device for coating a surface of the substrate, and a laser crystallization system for simultaneously illuminating at least one sub-partial area of a currently coated partial area of the surface of the substrate with at least one laser beam. The installation further includes a transport device for transporting the substrate in a feedthrough direction from the supply opening to the discharge opening and for continuously or discontinuously moving the substrate during the coating thereof in the feedthrough direction.

### CROSS-REFERENCE TO RELATED APPLICATIONS

This application is a continuation of, and claims benefit under 35 USC 120 to, international application PCT/EP2008/001465, filed Feb. 25, 2008, which claims benefit of U.S. Ser. No. 60/903,739, filed Feb. 27, 2007. International application PCT/EP2008/001465 is hereby incorporated by reference in its entirety.

### FIELD

The disclosure relates to a continuous coating installation, such as for producing nano-, micro-, poly-, multi- or monocrystalline thin films, referred to hereinafter generally as crystalline thin films. The disclosure also relates to a method for producing crystalline thin films, such as for producing a silicon tandem solar cell. The disclosure further to a tandem solar cell which can be produced using the methods disclosed herein.

### BACKGROUND

Semiconductor components used in microelectronics and photovoltaics are predominantly based on the semiconductor material silicon. The single-crystal semiconductor wafers which have predominantly been used since the 1960s and into which the corresponding structures are introduced are increasingly being replaced by thin films applied, e.g., to glass substrates.

Different modifications of the silicon, namely amorphous or crystalline silicon, occur depending on the deposition method used for such thin films. In general, the electronic properties of amorphous silicon differ significantly from those of crystalline silicon. On account of its optical/electronic properties and also on account of the possible deposition/production methods, amorphous silicon is suitable, for example, for producing thin-film solar cells. Thin films composed of crystalline silicon are of interest both for microelectronics and for photovoltaics. Flat screens are nowadays already produced on the basis of amorphous or polycrystalline silicon layers.

A large number of methods are known which permit amorphous silicon layers to be deposited cost-effectively, in large-area fashion and with sufficient layer thickness. They include various chemical vapour deposition (CVD) processes and physical vapour deposition (PVD) processes, such as, e.g., electron beam evaporation and cathode sputtering.

A large number of methods are also known for depositing crystalline thin films. In general, however, the deposition rates for producing the crystalline thin films are too low to be able to produce high-quality semiconductor structures cost-effectively. It is known, e.g., to produce finely crystalline silicon layers with the aid of chemical vapour deposition processes. In this case, however, the growth rate is generally only a few tens of nanometres per minute. Thin films produced by high-rate methods such as, e.g., electron beam evaporation or cathode sputtering generally have an amorphous microstructure and generally are not readily suitable for electronic components.

The polycrystalline silicon films for producing flat screens typically have layer thicknesses of between 50 and 100 nm. Polycrystalline thin films of this type can be produced from amorphous silicon films by, for example, thermal action or by irradiation with the aid of a high-power laser. Customary laser crystallization methods are the methods known by the respective following designations: laser zone melting, excimer laser annealing (ELA), sequential lateral solidification (SLS), and thin beam directional crystallization (TDX). Solid phase crystallization (SPC) and metal induced crystallization (MIC) and also halogen lamp and hot wire annealing (HW-CVD) are known among the thermal methods.

The process temperature and the glass substrate types can be important with regard to the production costs. Excimer-laser-based crystallization methods and also ion beam assisted deposition (IAD) are possible on low-temperature substrates, while SPC and MIC generally involve medium temperatures (approximately 400° C.-600° C.). Details are described for example in A. Aberle, Thin Solid Films 511, 26 (2006).

An absorber of a solar cell based on crystalline silicon generally involves a minimum layer thickness of 1 to 2 μm. Thermal crystallization of an amorphous silicon film may not suitable for producing crystalline silicon layers having crystallites of significantly larger than approximately 1 μm. With the aid of laser processes, although thin films having thicknesses of more than 200 nm can be crystallized, there can be difficulty with process control. Details are described by e.g. M. A. Crowder et al. in “Sequential Lateral Solidification of PECVD and Sputter Deposited a-Si Films” Mat. Res. Soc. Symp. Proc. Vol 621 (2000), Q9.7.1.

### SUMMARY

In some embodiments, the disclosure provides a continuous coating installation suitable for depositing high-quality crystalline thin films, as well as a corresponding method for producing crystalline thin films and solar cells and also a solar cell which can be produced, for example, by such a method.

In certain embodiments, a continuous coating installation includes a vacuum chamber having a supply opening for supplying a substrate to be coated and a discharge opening—usually arranged opposite—for discharging the coated substrate. The supply and/or discharge openings can be part of a lock system. It is also possible for further coating and/or processing chambers to be adjacent to the supply and/or discharge openings.

A continuous coating installation can also include a physical vapour deposition device (that is to say a deposition device for carrying out a physical vapour deposition method) arranged in the vacuum chamber and for coating a surface of the substrate. A deposition device of this type can include, for example, an electron beam evaporation device or a cathode sputtering device. Also possible are thermal evaporation devices that permit the deposition of thin films up to a few micrometres with a high deposition rate (in comparison with customary CVD methods).

A laser crystallization system can also be included in a continuous coating installation. The laser crystallization system can be arranged in relation to the deposition device in such a way that a laser beam provided for the laser crystallization can be directed onto a sub-partial area of a partial area of the surface of the substrate that is currently being coated by the deposition device. It can be desirable for a laser crystallization of the layer deposited onto the sub-partial area to be effected simultaneously during the coating of the partial area of the substrate surface.

The substrate can be fed through the coating and laser crystallization zone within the vacuum chamber. For this purpose, a transport device can be provided for transporting the substrate in a feedthrough direction from the supply opening to the discharge opening and for continuously or discontinuously, e.g., in stepwise fashion, moving the substrate during the coating thereof in the feedthrough direction. Optionally, a reversal of the direction of movement can also take place for a predetermined period of time or else periodically, if appropriate, but the uncoated substrate is generally supplied through the supply opening and discharged through the discharge opening.

In some embodiments, a plurality of electron beam evaporation devices and/or a plurality of cathode sputtering devices are arranged alongside one another perpendicular to the feedthrough direction. This can allow for comparatively wide substrates can also be coated. It is also possible for a plurality of PVD devices to be arranged one behind another in the feedthrough direction.

In certain embodiments, a transport device can have a movement device for moving the substrate in a direction that lies in a coating plane and runs at an angle, such as perpendicular, to the feedthrough direction. It is thus possible for both the currently coated partial area and the sub-partial area of the substrate surface that is currently being illuminated by the laser crystallization system to be chosen independently of the feedthrough direction.

In the simplest case, the laser crystallization system may be formed in rigid fashion. To put it another way, the laser beam or, if appropriate, laser beams emitted by the laser crystallization system are directed onto the substrate in a positionally fixed manner. Only the movement of the substrate in the feedthrough direction or, if appropriate, in a direction at an angle, such as perpendicular, thereto leads to a change in the sub-partial areas exposed to the laser beam or laser beams. It can be expedient, e.g., to carry out the movement of the substrate in meandering fashion.

Instead of or in addition to a movement of the substrate by the transport device, the laser beam or laser beams for crystallization may perform the movement of the substrate. For this purpose, the laser crystallization system itself can have one or more laser beam movement devices that can be moved in at least one direction in order to guide at least one of the laser beams directed onto the substrate over the currently coated partial area independently of the movement of the substrate.

Depending on the arrangement, it can be sufficient to provide only one movement in a linear direction. As the substrate size increases, it may be desirable for a laser beam movement device to be capable of being moved in two directions running at an angle, such as perpendicular to one another, in which case one direction can coincide with the feedthrough movement direction. This may be expedient, for example, if the laser beam describes a meandering path. Movements on curved movement paths are also conceivable. However, the latter movements, owing to their complexity, are generally taken into consideration only when they are advantageous for process-technological reasons.

In some embodiments, a laser beam movement device has a linear motor for linearly moving the at least one laser beam movement device.

In principle, it is possible to move the entire laser crystallization system. In order to keep the moved masses small, however, it is often more expedient to move only individual optical components. A particularly advantageous configuration, which is distinguished by its simplicity and extensive minimization of the masses to be moved, provides for a laser beam movement device to have a moveable mirror that deflects the at least one laser beam onto the at least one sub-partial area. A suitable arrangement of this or, if appropriate, the plurality of such deflection mirrors makes it possible to direct the laser beam or laser beams at each desired location on the substrate.

Instead of linear movement devices for the substrate and/or for the laser crystallization system or for optical components thereof, the laser crystallization system can have at least one laser angle scanner which can be rotated about at least one axis in order to direct the at least one laser beam onto the substrate from different directions. Such scanners can allow for very rapid changes in the current impingement location or current impingement locations of the laser beam or laser beams on the substrate. This can result from the fact that large changes in the impingement location on the substrate can be realized with small angular changes. While oscillating movements of the substrate and/or of the laser crystallization system or optical components thereof with amplitudes of a number of centimetres will be restricted to frequencies of a few hertz, angular scanning movements of a laser beam are possible with a frequency of thousands of hertz in the case of mechanical mirrors or holographic scanners and in the MHz range in the case of acousto-optical scanners.

In certain embodiments, at least one laser angle scanner can be pivoted about at least one second axis. With a single laser beam, given a suitable arrangement of the axes with respect to one another (provided that there are no other obstacles) it is possible to illuminate each location on the substrate without the substrate itself needing to be moved.

Optionally, the laser crystallization system has at least one further laser angle scanner which is assigned to the at least one laser angle scanner and can be pivoted about at least one axis in order to direct the at least one laser beam onto the at least one laser angle scanner.

In some embodiments, at least one imaging objective is provided in order to image the at least one laser beam onto the substrate surface in such a way that the contour and size of the sub-partial area illuminated by the laser beam remain essentially unchanged if the at least one laser beam is directed onto the substrate from different directions. The generation of a laser spot (generally in the form of a focus) that is independent of the irradiation direction in terms of contour and size is practical for setting a predetermined energy or power density distribution involved for the laser crystallization on each location of the substrate. If the spot size (focus size) changed depending on the irradiation angle, there would be the risk of an inhomogeneous crystallization over the substrate area. What is more, part of the laser energy would possibly not contribute to the crystallization of the substrate.

One variant of a laser angle scanner and/or of a further laser angle scanner can have one or a multiplicity of galvo-mirrors or- scanners in order to deflect the at least one laser beam in a different manner. Rotating polygon scanners can also be used instead of one-or two-dimensional galvo-scanners. Polygon scanners can be operated at very high rotational speed, such that they enable scanning rates of more than 1000 Hz. Further variants of scanners are acousto-optical scanners and holographic scanners. The former can permit high scanning rates, for example, and the latter can permit different foki of the laser beam.

In some embodiments, a multiplex device is used for generating a plurality of laser beams for simultaneously illuminating a plurality of sub-partial areas. The simultaneous illumination of a multiplicity of sub-partial areas has the advantage that, for the same spot scanning speed, either the feedthrough speed of the substrate or the deposition rate or both can be increased. All the measures can lead to an increase in the throughput or to a reduction of the costs by virtue of less stringent desired properties made of the optical system components.

In the simplest case, a multiplex device of this type can include a beam subdividing device for subdividing a laser beam into the plurality of laser beams. Roof prisms or multiple prisms as well as diffractive elements are examples of such beam subdividing devices. Assuming by way of example that the substrate surface forms a field plane onto which the laser beam or laser beams is or are imaged, the prisms can be arranged in a pupil plane.

A further variant of a continuous coating installation includes a deposition measuring device for measuring a deposition rate and/or a deposition quantity of a material deposited by the vapour deposition device, and also an open-loop and/or closed-loop control device for the open-loop and/or closed-loop control of the movement of the transport device and/or the laser beam movement device and thus for defining the location on the substrate onto which the (respective) laser beam is currently directed depending on the measured deposition rate and/or the measured deposition quantity. As an alternative or in addition, the open-loop and/or closed-loop control device can also be provided for the open-loop and/or closed-loop control of the current intensity of the at least one laser beam on the substrate depending on the measured deposition rate and/or the measured deposition quantity.

In some embodiments, as an alternative to the deposition measuring device described above or as an additional functional module, a layer thickness measuring device for measuring a layer thickness change and/or a layer thickness of the layer deposited on the substrate, e.g., by reflection or transmission at one or more wavelengths, ellipsometry or profilometry. The abovementioned open-loop and/or closed-loop control device or a corresponding open-loop and/or closed-loop control device can be provided for effecting open-loop or closed-loop control of the movement of the transport device and/or the laser beam movement device and/or the current intensity of the at least one laser beam on the substrate depending on the measured layer thickness change and/or the measured layer thickness. The open-loop and/or closed-loop control of the movement of the transport device and/or the laser beam movement device defines the current location of the respective sub-partial area on the substrate, that is to say the location on the substrate onto which the respective laser beam is currently directed.

It goes without saying that the disclosure not only relates to a continuous coating installation as an overall system, rather it should be directly apparent to the person skilled in the art that the above-described variants of laser crystallization systems can also be operated by themselves, that is to say independently of a coating installation, or as part of a batch installation.

In certain embodiments, a method for producing nano- micro-, poly- multi- or monocrystalline thin films, includes supplying a substrate to be coated into a vacuum chamber in a feedthrough direction. The method also includes physical vapour deposition of a layer onto a partial area of a surface of the substrate and simultaneously at least partial melting and subsequent crystallization inducing illumination of at least one sub-partial area of the currently coated partial area of the surface of the substrate by at least one laser beam while continuously or discontinuously moving the substrate in the feedthrough direction. The method further includes discharging the coated substrate from the vacuum chamber in the feedthrough direction.

Physical vapour deposition can include electron beam evaporation or cathode sputtering. It can be expedient for the physical vapour deposition to be carried out at a layer growth rate of. more than 100 nm/min (e.g., more than 1000 nm/min, more than 2000 nm/min). The deposition rate therefore can differ considerably from customary CVD processes. Even the growth rates of layers deposited by plasma enhanced chemical vapour deposition (PECVD) processes generally lie at most at the lower limit of the range of values specified above.

On account of the high possible deposition rates of PVD processes generally and of electron beam evaporation and sputtering in particular, it can be possible to move the substrate during the physical vapor deposition/melting/crystallization step in the feedthrough direction at an average speed of more than 0.5 m/min, such as more than 2 nm/min, depending on the availability of commercial high-power lasers. The throughput time can therefore be significantly increased, which can result in a considerable reduction of production costs.

In certain embodiments, the substrate is moved during the physical vapor deposition/melting/crystallization step in a direction that lies in a coating plane and is perpendicular to the feedthrough direction. Both the current location of the coating and the current location of the laser-induced crystallization of the substrate can be defined continuously in this way.

Optionally, the substrate is moved in oscillating fashion during the physical vapor deposition/melting/crystallization step in the direction that lies in the coating plane and is perpendicular to the feedthrough direction or in the feedthrough direction. Each desired part of the substrate is subjected (given a correspondingly adapted feedthrough speed) multiply to a coating and laser-induced crystallization process. In this case, the energy density of the laser beam or laser beams can optionally be set in such a way that the newly applied material only melts superficially, that the layer applied during a cycle melts over its entire layer thickness, or that one or more lower layers applied in previous cycles is or are even melted completely or over a fraction of its or their layer thickness.

The oscillating movement can be effected periodically at a frequency of 200 to 500 mHz. In this case, it may be advantageous if the forward movement takes place very slowly and the backward movement (e.g. along the same path) takes place very rapidly, that is to say, e.g., in less than 1/100 or 1/1000 of the time of the forward movement. If different areas on the substrate are illuminated during forward and backward movements, e.g. if the laser beam progresses on a meandering path on the substrate, it is generally more favourable not to change the speed of the movement.

In some embodiments, at least one of the laser beams is guided over the currently coated partial area in a manner dependent on or independently of the movement of the substrate during the physical vapor deposition/melting/crystallization step. Consequently, the respective laser beam is scanned over the surface of the substrate not only owing to the substrate's own movement, but on account of a movement of the laser beam.

It can be particularly expedient if the at least one of the laser beams is guided over the currently coated partial area in a feedthrough direction of the substrate or at an angle, such as a right angle, to the feedthrough direction.

Once again it can be expedient if the movement is effected periodically. Scanning rates of 200 to 500 mHz or even higher are expedient depending on the respective deposition rates. In this case, too, it may be advantageous if the forward movement takes place very slowly and the backward movement takes place very rapidly, that is to say e.g. in less than 1/1000 or in less than 1/100000 of the time of the forward movement. It may be practical for the substrate to be illuminated only during the forward movement of the device that directs the laser beam onto the substrate, but not during the backward movement of the device. If the laser is operated in pulsed fashion, then it may be desirable for the backward movement to take place only precisely within the dead time within which no laser pulse is emitted.

This is different, of course, if the laser beam is guided on a meandering path over the substrate. A constant speed of the progressing laser spot on the substrate is advantageous in this case.

It has proved to be particularly advantageous if the at least one of the laser beams is directed at that location of the substrate onto which precisely a predetermined layer thickness, e.g., between 50 nm and 1000 nm (e.g., between 100 nm and 500 nm, between 100 nm and 300 nm) has been deposited. This operation can be repeated multiply in accordance with the above explanations until the final layer thickness is reached. The alternation of deposition and laser crystallization need not necessarily be effected in constant periods in this case. A particularly advantageous variant of the disclosure consists in laser-crystallising the bottommost layers on the substrate already after the growth of small layer thicknesses and, once a certain crystallized layer thickness has grown, in depositing a thicker layer by the PVD method before a further laser crystallization is initiated. It is particularly advantageous if the laser crystallization of the upper layers is carried out with low laser fluence in order to avoid melting of the underlying layers and mixing of dopings. It is thus expedient, for example, to crystallize the last n-type layer of a μc-Si cell, i.e. the collector layer, with low laser fluence in order to avoid mixing with the dopings of the underlying i- or p-type layer(s).

The temperature of the substrate can be kept constant e.g. between 200° C. and 400° C. (depending on the glass substrate used) during the physical vapor deposition/melting/crystallization step. This can be achieved by an additional thermal heating and/or cooling of the substrate and/or by a corresponding adaptation of the laser fluence.

The method described above is suitable, in principle, for coating the substrate with virtually any desired material. Owing to the large field of application in electronics and photovoltaics, it may be desirable to apply the method with silicon.

The laser beam or the laser beams can have a wavelength of between 150 and 800 nm. In general, it suffices to illuminate the substrate by one or a plurality of lasers of a single wavelength. However, provision is also made for using lasers of different wavelengths. The corresponding laser beams can be directed simultaneously or successively onto the same location or the same locations of the substrate.

The laser wavelength may depend on the different process windows of the individual method steps and the different respective structures of the electronic components to be produced. If production of an a-Si/μc-Si tandem solar cell is assumed, then the laser wavelength to be used depends concretely on the silicon microstructures of the different tandem cell types. The microstructure and morphology of the deposited Si, i.e. a-Si or already crystallized μc-Si, determines together with the wavelength the absorption length and thus together with the laser power, the pulse duration (if appropriate also infinite when using a CW laser), the temporal pulse profile, the laser beam profile on the Si layer and the temporally varied reflectivity R thereof (R_{a-Si}≈R_{μc-Si}≈R_{liquid Si})/the 3-dimensional temperature profile in the Si layer. The absorption length of an excimer-laser-emitted light at e.g. 193 nm, 248 nm, 351 nm with typical pulse durations of approximately 20 nsec is a few nanometres, while light from diode pumped solid state lasers (DPSSL), such as e.g. frequency-doubled Nd: YLF, Nd: YAG, or Nd: YVO₄ lasers, at 532 nm, is absorbed within significantly greater absorption lengths and therefore heats the layer more uniformly in the depth. Lower laser powers per cm² (i.e. laser fluences) are involved for producing thin (seed) layers for example according to the SLS² methods. Therefore, it can be particularly energy-efficient firstly to crystallize a thin seed layer by an excimer laser and then, by a laser having a longer wavelength (e.g. DPSSL) , in a further step to crystallize a thicker a-Si layer deposited onto the seed layer. In the case of the tandem cell mentioned above, e.g. an excimer laser which emits light with a short absorption length can again be used for the final thin n-doped collector layer.

For the method described below of laser crystallization by a “self propagating liquid layer”, a pulsed long-wave laser is advantageous in order to produce a temperature profile in the depth of the layer which enables a longest possible propagation of the “liquid layer” and therefore a largest possible layer thickness per crystallization step before the process ends for energetic reasons. A preheating of the Si layer (e.g. by halogen lamps) in combination with a UV excimer laser is also possible here, although then only with glass substrates which withstand these temperatures. If appropriate, additional diffusion barriers can be provided in order to prevent the diffusion of impurities and dopings from the substrate into the solar cell or within the cell. Depending on the layer thickness and wavelength, the laser fluencies are approximately 150-500 mJ/cm² for thin seed layers and the method with “self propagating liquid layer” and also <<500-1500 mJ/cm² for the crystallization of thicker layers (100-500 nm) in the “complete melting” or “near complete melting” region, where “complete melting” relates to the a-Si layer and not to a previously crystallized underlying μc-Si or PECVD a-Si layer.

It can be particularly advantageous for high throughput and low production costs of the continuous coating installation for the laser radiation to be reflected back after reflection at the a-Si or melted Si layer by mirrors onto the same location again in order to increase the power or to reduce the desired laser power under the same process conditions. On account of the high reflectivity of the melted silicon, approximately 50% depending on angle of incidence and wavelength, the efficiency of the installation can be increased by this “beam recycling”.

The disclosure provides methods for producing a silicon tandem solar cell including at least one solar cell based on amorphous silicon and at least one solar cell based on crystalline silicon, which are arranged one above another. Such methods can include providing a solar cell based on amorphous silicon on a transparent substrate, and producing a solar cell based on crystalline silicon.

Producing a solar cell based on crystalline silicon can include: a) providing or applying a p-doped or, in an alternative embodiment, n-doped optionally amorphous or crystalline silicon layer; b) optionally providing or applying a seed and/or buffer layer composed of intrinsic crystalline silicon; c) depositing an amorphous silicon layer with the aid of a physical vapour process; d) crystallising the amorphous silicon layer produced with the aid of the physical vapour process with the aid of a laser crystallization process; e) optionally multiply repeating method substeps c) and d); f) optionally applying or providing an n-doped silicon layer or, alternatively, p-doped optionally amorphous or crystalline silicon layer; g) optionally crystallising the amorphous n-doped or, alternatively, p-doped silicon layer by a laser crystallization process; and h) depositing a conductive contact.

Optionally, a hydrogen passivation can be carried out after the last laser crystallization and/or after completing the solar cell based on crystalline silicon.

Steps c) to e) above can be carried out according to the method described in the previous sections.

In some embodiments, a method includes: i) depositing a transparent conductive layer on the transparent substrate; ii) depositing a p-doped or, alternatively, n-doped amorphous silicon layer; iii) optionally depositing an intrinsic amorphous silicon layer; and iv) depositing an amorphous n-doped silicon layer or, alternatively, p-doped silicon layer.

A tandem solar cell or multi-solar cell can include at least one solar cell based on amorphous silicon and at least one solar cell based on nano-, micro-, poly-or microcrystalline silicon, which are arranged monolithically one above another. The solar cell based on crystalline silicon can have an intrinsic silicon layer, and the intrinsic silicon layer having crystallites having grain diameters of between 20 nm and 5 um.

### BRIEF DESCRIPTION OF THE DRAWINGS

The disclosure will now be described in more detail with reference to the drawing. Identical or functionally identical constituent parts of the devices illustrated in the various figures are provided with identical reference symbols. In the figures:

FIG. 1 shows a basic illustration of a continuous coating installation for coating a substrate and subsequent laser crystallization of the deposited layer;

FIG. 2 shows the substrate in the continuous coating installation according to FIG. 1 from below;

FIG. 3 shows a continuous coating installation with a first embodiment variant of a laser crystallization device,

FIG. 4 shows a continuous coating installation,

FIG. 5 shows a continuous coating installation;

FIG. 6 shows a continuous coating installation;

FIG. 7 shows a continuous coating installation;

FIG. 8 shows an a:Si/μc-Si tandem solar cell;

FIG. 9 shows a method for producing the crystalline silicon cell of the tandem solar cell according to FIG. 8;

FIG. 10 shows a method for producing the crystalline silicon cell of the tandem solar cell according to FIG. 8;

FIG. 11 shows a method for producing the crystalline silicon cell of the tandem solar cell according to FIG. 8;

FIG. 12 shows a method for producing the crystalline silicon cell of the tandem solar cell according to FIG. 8;

FIG. 13 shows a method for producing the crystalline silicon cell of the tandem solar cell according to FIG. 8;

FIG. 14 shows a method for producing the crystalline silicon cell of the tandem solar cell according to FIG. 8; and

FIG. 15 shows a method for producing the crystalline silicon cell of the tandem solar cell according to FIG. 8.

### DETAILED DESCRIPTION

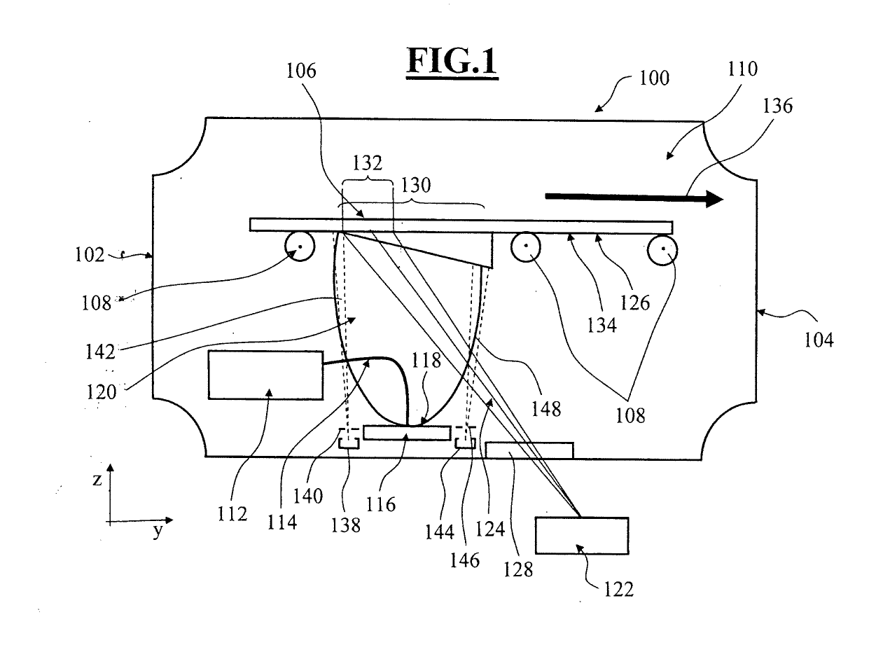

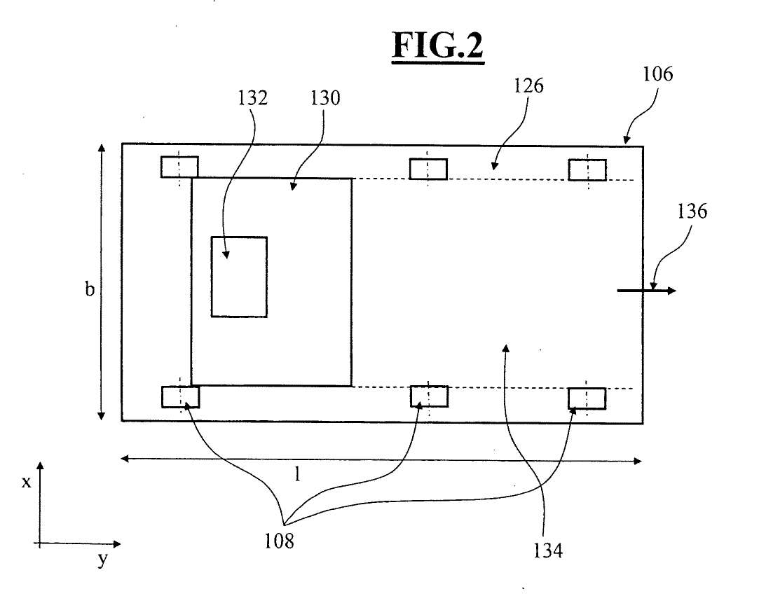

FIGS. 1 and 2 show the basic construction of a continuous coating installation 100 from different viewing angles. FIG. 1 shows a side view (yz plane), and FIG. 2 shows a view from below (xy plane). The continuous coating installation 100 is a vacuum installation and accordingly includes a vacuum chamber 110. The vacuum chamber 110 has a supply opening 102 and a discharge opening 104 arranged opposite. Adjacent to supply and/or discharge opening 102, 104 there may be in each case a lock system and/or a further process chamber, such as a further vacuum chamber (not illustrated).

Continuous coating installation 100 also includes a substrate holder 108 with transport rollers. The substrate holder 108 serves, on the one hand, for the placement of a substrate 106 and, on the other hand, also as a transport device to transport the substrate 106 having an edge length 1 and a width b from the supply opening 102 in feedthrough direction 136 to the discharge opening 104.

An evaporator crucible 116 of an electron beam evaporation device 112 is arranged below the substrate holder 108. It is assumed for purposes of discussion that silicon 118 is situated in the evaporator crucible 116. The silicon can be evaporated by the electron beam 114 to form a largely directional vapour jet 120 that can deposit silicon on the surface 126 of the substrate 106 facing the crucible 116. Instead of the electron beam evaporation device 112, a cathode sputtering device could also be provided, in which case the latter would more likely be situated above the substrate 106.

It is evident from FIGS. 1 and 2 of the drawing that the vapour jet 120 is directed only onto a partial area 130 of the surface 126 of the substrate 106. Since the substrate 106 is moved in feedthrough direction 136, the layer thickness deposited onto the substrate 106 by the device 112 increases within the partial area 130 from the side of the substrate 106 facing the supply opening 102 to the side of the partial area 130 facing the discharge opening 104 (linearly given constant feedthrough speed). A layer that has already reached the final layer thickness is situated on that part of the substrate 106 which has already emerged from the vapour jet 120. The corresponding partial area which has already been completely coated is identified by the reference symbol 134 in the drawing.

The drawing furthermore illustrates two effusion cells 138, 144 for doping with phosphorus (n-type conduction) or boron (p-type conduction). The effusion cells 138, 144 are optional. When present, they can be heated either electrically or with the aid of an electron beam. The effusion cells 138, 144 are designed so that the doping impurity atoms impinge by geometrical shading and gap delimitation 140, 146 in spatially narrowly delimited vapour jets 142, 148 on narrow (a few centimetres wide) partial sections of the substrate. Transversely with respect to the feedthrough direction 136, the effusion cells 138, 144 have approximately the width b of the substrate 106.

Installation 100 also includes a laser crystallization system 122. The optical components of the laser crystallization system 122 are situated outside the vacuum chamber 110. The laser crystallization system 122 emits a laser beam 124. The laser beam 124 is directed through a chamber window 128 in the vacuum chamber 110 onto a location—referred to hereinafter as sub-partial area 132—of the surface 126 of the substrate 106. The sub-partial area 132 is part of the currently coated partial area 130 situated in the directed vapour jet 120, and if appropriate of the currently coated partial area 130 situated in the directed vapour jets 142, 148, of the surface 126 of the substrate 106.

The laser beam 124 is guided repeatedly over the simultaneously coated partial area 130 by a suitable movement of the substrate 106 and/or a suitable movement of the laser beam 124 during the layer deposition and/or the material melts at least part of its layer thickness, however. When the melted material cools down, crystallization takes place to form a layer having a fine—or coarse—grained structure, i.e. Si crystallites separated by grain boundaries.

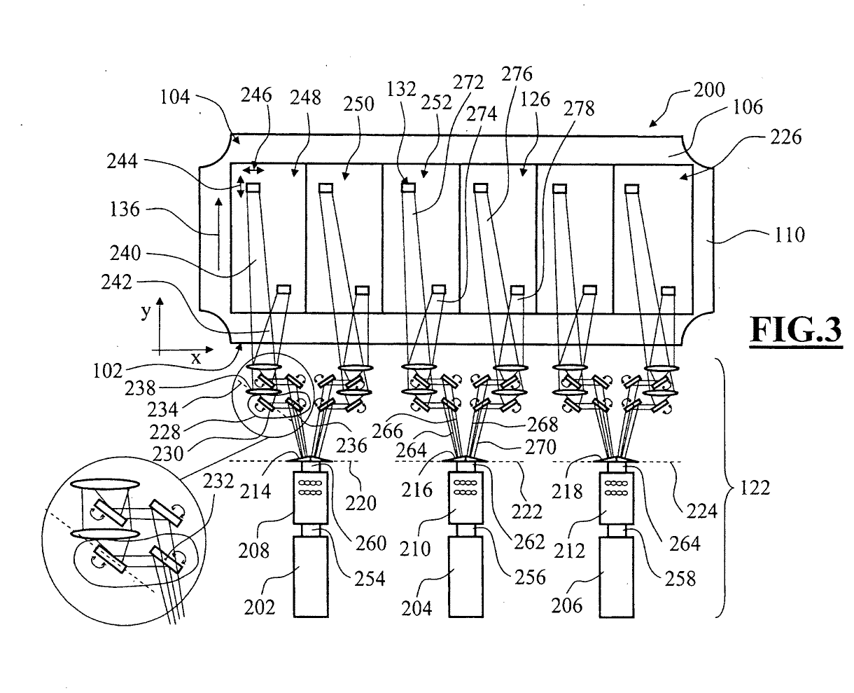

FIG. 3 shows a coating installation 200 with a first embodiment variant of a laser crystallization system 122. The basic illustration reveals a vacuum chamber 110 with supply and discharge opening 102, 104 and chamber window 128.

Constituent parts of the installation 200 are, alongside the laser crystallization system 122, a transport device (not illustrated here) and also a PVD coating device (likewise not illustrated) (if appropriate with effusion cell(s)) of the type shown in FIGS. 1 and 2.

In this embodiment variant according to FIG. 3 , the laser crystallization system 122 includes three lasers 202, 204, 206. The latter emit laser beams 254, 256, 258 having a power of 300 watts, a pulse frequency of 300 hertz and a laser energy of one joule per pulse.

The laser beams 254, 256, 258 are respectively directed onto two-dimensional single-stage homogenizers 208, 210, 212. The homogenized laser beams 260, 262, 264 emerging from the homogenizers 208, 210, 212 on the output side respectively impinge on so-called quad prisms 214, 216, 218, where they are respectively subdivided into four partial beams having a correspondingly reduced power. Four of these subdivided laser beams are provided with the reference symbols 264, 266, 268 and 270, by way of example. These twelve subdivided laser beams 264, 266, 268, 270 are respectively directed via two-dimensional galvo-scanners 228 each having two galvo-mirrors 230, 232 and an objective 238 arranged in the chamber window plane onto the surface 226 of the substrate 106. The rotation axes 234, 236 of the galvo-mirrors 230, 232 are oriented with respect to one another in such a way that the respective laser beam 240, 242, 272, 274, 276, 278 deflected by the galvo-scanner 228 can be moved in substrate longitudinal direction 244 and in substrate transverse direction 246 over the surface 226 of the substrate 106.

Each of the twelve laser beams 240, 242, 272, 274, 276. 278 produces a respective spot size of 7 cm×7 cm in the example given a working distance of 50 cm on the surface 226 of the substrate 106. Each laser spot can be guided over a partial field 248, 250, 252 of 20 cm×20 cm of the surface 126 of the substrate 226.

For the SLS² or TDX² method described below for producing larger crystallites with fewer grain boundaries per cm² at the beginning of the laser crystallization on a PECVD a-Si layer, a line focusing of the laser beam in orthogonal directions successively, e.g. in x and y directions, is desired. This is possible using the optical system according to FIG. 3 by splitting the laser beam and producing different beam profiles by a plurality of homogenizers, i.e. one homogenizer for the line focus in the x direction (scanning direction x and y), a further homogenizer for the line focus in the y direction (scanning direction x and y) and also one homogenizer for the square laser profile described. However, rotation about the beam direction of a homogenizer, particularly in the case of combination of SLS and ELA, or rotation of the beam profile by prisms or plane mirrors is possible. In any case the laser power splitting of the lasers has to be matched to the desired process parameters of the individual processes. As an alternative, the SLS² method can be carried out with SLS slotted masks, although with lower efficiency. As an alternative and in a departure from the continuous concept, it is possible to rotate the substrate for implementing the SLS² or TDX₂ method.

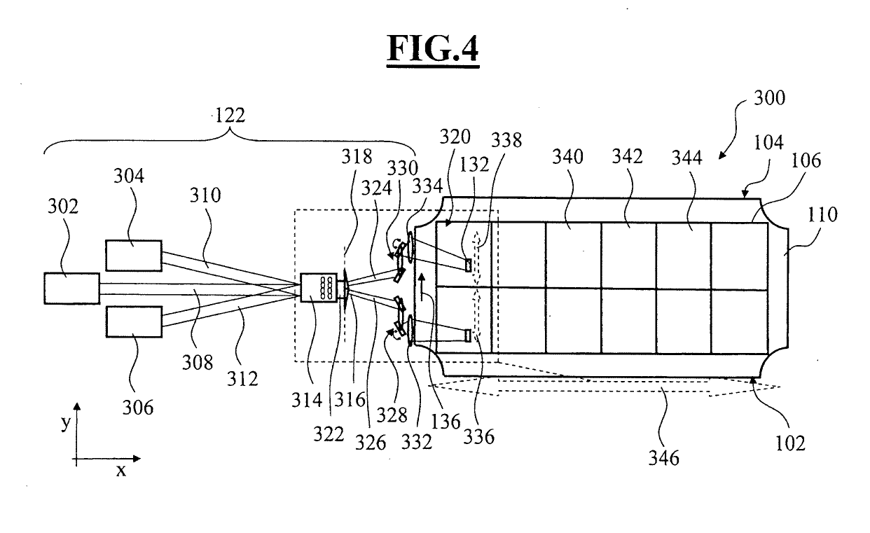

FIG. 4 shows a further exemplary embodiment of a continuous coating installation 300. The vacuum chamber 110 with supply opening 102 and discharge opening 104 is once again depicted schematically. Situated in the interior of the vacuum chamber 110 there is once again a substrate 106, which can be moved in feedthrough direction 136 with the aid of a transport device (not illustrated) from the supply opening 102 to the discharge opening 104. A PVD coating device (not illustrated) is once again arranged within the vacuum chamber 110. A sputtering device which is arranged above the substrate 106 but is not depicted is assumed in the present case.

Through a chamber window 128 (not illustrated) in the cover of the vacuum chamber 110, it is possible to illuminate the substrate surface 320 by laser spots 132 produced by a laser crystallization device 122.

In the present exemplary embodiment, the laser crystallization device 122 includes three lasers 302, 304, 306 having a power of in each case 300 watts, a repetition rate of 300 hertz and a pulse energy of 1 joule. The lasers 302, 304, 306 are pulsed in synchronized and intermittent fashion such that the arrangement illuminates the surface of the substrate 106 with an effective total pulse rate of 900 hertz.

The laser beams 308, 310, 312 emitted by the three lasers 302, 304, 306 are fed to a two-dimensional single-stage homogenizer 314 on the input side. The laser beam 322 homogenized by the homogenizer 314 is subdivided, with the aid of a roof prism 316 arranged in a pupil plane 318 (the field plane is situated on the substrate surface), into two partial beams 324, 326 having a correspondingly reduced laser power and is deflected in different directions.

Each partial laser beam 324, 326 is directed via a one-dimensional galvo-scanner 328, 330 onto an imaging objective 332, 334, which produces a laser beam profile 132 on the substrate 106. The laser beam profile size on the substrate 106 is 10 cm×10 cm in the present exemplary embodiment. The galvo-scanners 328, 330 respectively enable the laser beam profiles 132 to be moved in and counter to the feedthrough direction 136. The corresponding directions of movement are indicated in the drawing by arrows provided with the reference symbols 336, 338. In this case, each of the two laser beam profiles 132 can scan half the substrate length 1. In order to be able to direct the laser beam profiles 132 onto each location of the substrate surface, provision is made for the substrate 106 itself to be able to move to and fro perpendicular to the feedthrough direction 136. The possibility of movement to and fro is in turn illustrated in the drawing with the aid of a double-headed arrow 346.

The installation according to FIG. 4 also makes it possible to simultaneously carry out different processes such as SLS, SLS² and ELA by rotating the beam profile (homogenizer), producing different beam profiles (e.g. linear and rectangular) and/or providing different distributions of the laser power between the two scanners 328, 330, e.g. by displacing the roof prism 316.

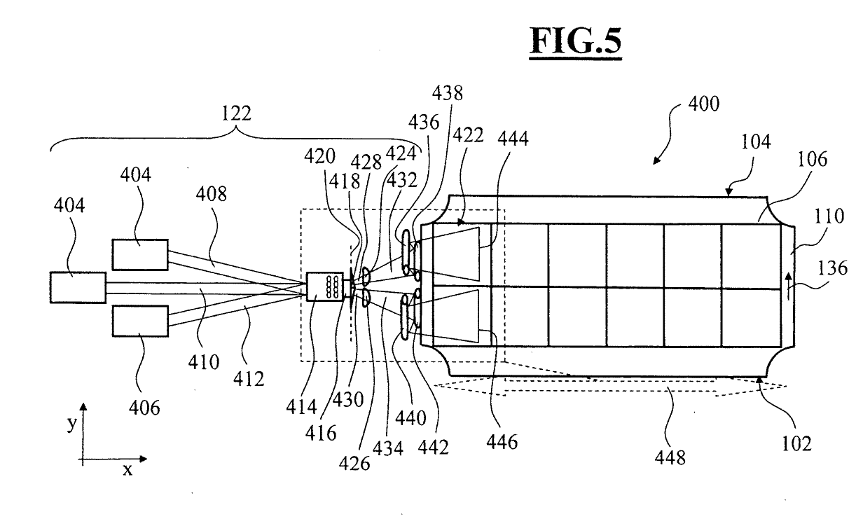

FIG. 5 shows a further continuous coating installation 400 with a third embodiment variant of a laser crystallization device 122.

The continuous coating installation 400 again includes a vacuum chamber 110 with a supply opening 102, via which a substrate 106 can be supplied in feedthrough direction 136, and with a discharge opening 104, via which the substrate 106 can be removed in feedthrough direction 136. A constituent part of the continuous coating installation 400 is once again a PVD coating device (not illustrated), which can be arranged above or below the substrate 106. In this respect, the continuous coating device 400 is identical to that according to FIG. 4.

A third embodiment variant of a laser crystallization device 122 is depicted as a further constituent part of the continuous coating installation 400 in FIG. 5 of the drawing. As in the previous exemplary embodiment, the laser crystallization device 122 includes three lasers 402, 404, 406 having a power of 300 watts, a repetition rate of 300 hertz and a pulse energy of 1 J/pulse. The lasers 402, 404, 406 are synchronized and emit laser pulses in each case at a time interval of ⅓ of the total period duration of a laser 402, 404, 406. The laser beams 408, 410, 412 emitted by the lasers 402, 404, 406 are in turn directed onto a two-dimensional single- or two-stage homogenizer 414. The laser beam 416 homogenized by the homogenizer 414 subsequently impinges on a roof prism 418 arranged in a pupil plane 420 corresponding to the field plane assumed on the substrate area. The roof prism 418 subdivides the homogenized laser beam 416 into two partial laser beams 428, 430 and deflects them in different directions in each case. The two partial laser beams 428, 430 respectively impinge on a beam expanding device 424, 426. Anamorphic lenses having a length of 20 cm are provided by way of example in the present exemplary embodiment. The expanded laser beams 432, 434 in turn impinge on a respective cylindrical lens objective (or alternatively on a cylindrical mirror objective) arranged in the chamber window 128 incorporated in the upper or lower part of the vacuum chamber 110 and having in each case two cylindrical lenses 436, 438, and 440, 442 arranged one behind another. These cylindrical lens objectives image the respective homogenized laser beam 432, 434 in reduced fashion, in each case forming an elongated illumination line with a defined homogenized beam profile 444, 446, onto the surface 126 of the substrate 106.

In the present exemplary embodiment, the length of an illumination line 444, 446 corresponds precisely to half the substrate length 1 in feedthrough direction 136. In practice, the lengths of the illumination lines 444, 446 will be chosen precisely such that together they correspond to the length of the partial area 130 of the surface of the substrate 106 which is exposed to the vapour jet 120 of the PVD device 112. The width of the illumination lines 444, 446 focused onto the substrate surface is 50 μm given a working distance of 50 cm. In order to expose the entire surface 126 of the substrate 106 to the laser radiation of the two illumination lines 444, 446, the substrate 106 can in turn be moved to and fro perpendicular to its feedthrough movement direction 136 over its entire width b. The moveability is once again indicated with the aid of a double-headed arrow, identified by the reference symbol 448.

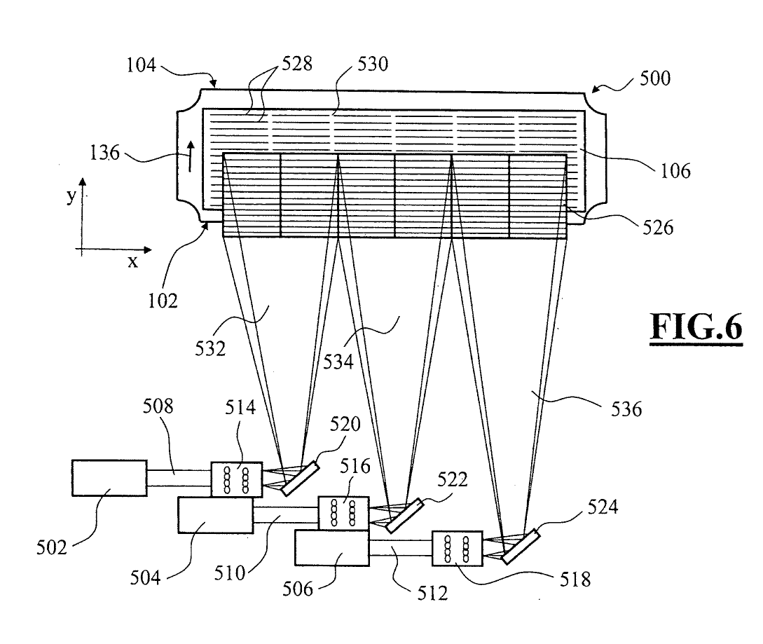

FIG. 6 shows a further exemplary embodiment of a continuous coating installation 500. As in the examples described above, once again its vacuum chamber 110 with supply opening 102 and discharge opening 104 and also the laser crystallization device 122 are outlined schematically.

The direction of movement of the substrate 106 is once again indicated with the aid of an arrow, identified by the reference symbol 136. The illustration does not show a PVD coating device likewise present and a chamber window through which the surface 126 nor of the substrate 106 is crystallized by a laser beam.

The laser crystallization device 122 once again includes three lasers 502, 504, 506 each having a power of 300 watts, a pulse frequncy of 300 hertz and a laser energy of 1 J/pulse. The laser beams 508, 510, 512 emitted by the lasers 502, 504, 506 are homogenized independently of one another with the aid of corresponding two-dimensional single- or two-stage homogenizers 514, 516, 518 and, after their homogenization, are respectively fed to a deflection mirror 520, 522, 524. These deflection mirrors 520, 522, 524 expand the laser beams 532, 534, 536 to the size of a cylindrical lens arrangement 526 situated in the chamber window 128. The cylindrical lens arrangement 526 focuses the laser beams 532, 534, 536 to form equidistantly arranged lines in the field plane 530 on the substrate. For this purpose, the cylindrical lens arrangement 526 includes 14×6=84 cylindrical lenses. The 84 cylindrical lenses are curved differently such that all of the foci in the substrate plane have the same geometrical shape and the same intensity profile, namely a 20 cm×36 μm homogeneous line profile. This embodiment variant is distinguished by the fact that no moveable parts are present and that the installation can easily be scaled. Only one large chamber window is involved and the dimensions of the installation overall are relatively large.

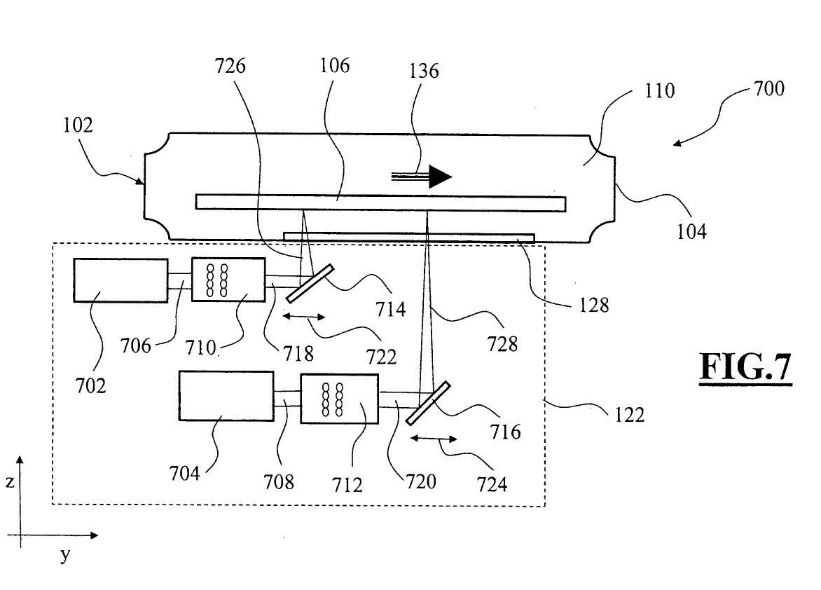

FIG. 7 shows a further exemplary embodiment of a continuous coating installation 700. The figure of the drawing once again reveals the vacuum chamber 110 with supply opening 102 and discharge opening 104 for the substrate 106, and with a chamber window 128 through which laser light for the crystallization of a layer deposited on the substrate 106 can be coupled in. The substrate 106 is transported by a transport device (not illustrated here) in the y direction from the supply opening 102 to the discharge opening 104. The direction of movement is marked in FIG. 7 by an arrow identified by the reference symbol 136.

The illustration here does not show the PVD coating system, which, in a similar manner to the embodiment variant illustrated in FIG. 1, can include a plurality of electron beam evaporation devices 112 arranged in the x direction.

The laser crystallization device 122 is depicted in the present case. It includes two lasers 702, 704, which can also be different laser types, i.e. excimer lasers and DPSSL (Diode Pumped Solid State Laser), CW or pulsed lasers having different wavelengths. The laser beams 706, 708 emitted by the lasers 702, 704 are homogenized with the aid of homogenizers 710, 712 and expanded in the x direction with the aid of an optical unit (not illustrated here). The expanded laser beams 718, 720 are directed onto the substrate 106 with the aid of deflection mirrors 714, 716. A focusing optical unit (likewise not illustrated here) before the chamber window 128 focuses the deflected laser beams 726, 728 onto the surface of the substrate 106. The two deflection mirrors 714, 716 can be moved linearly in the Y direction. The linear moveability is respectively indicated in the figure of the drawing by a double-headed arrow identified by the reference symbols 722, 724. The laser beams 726, 728 directed through the chamber window 128 onto the substrate can be directed onto different locations of the surface of the substrate 106 with the aid of these linearly moveable deflection mirrors 714, 716 during coating.

Table 1 presented below summarizes the various possibilities of guiding a laser beam over the entire substrate surface.

[symbol]

Table 1: Mechanical arrangements for illuminating different locations on a substrate passing through a continuous coating installation.

The first row and the first column of Table 1 respectively specify the device for moving the laser beam in the corresponding direction. It is assumed that the feedthrough direction of the substrate is the y direction.

To summarise, in each spatial direction x or y the laser beam can be immobile (column 2, row 2), be moved optionally linearly with the aid of a mechanical linear scanner (column 3, row 3) or be directed onto the substrate at different angles with the aid of an angle scanner (column 4, row 4) . If the movement of the substrate is disregarded, then nine variants for the illumination of the substrate are produced by permutation.

If the possibility of moving the substrate in the x and/or y direction (movement only in x direction, movement in x and y direction) is additionally taken into consideration, the number of variants is doubled. Furthermore, there is the possibility of illuminating the substrate surface with only one homogenized laser profile or with a multiplicity thereof.

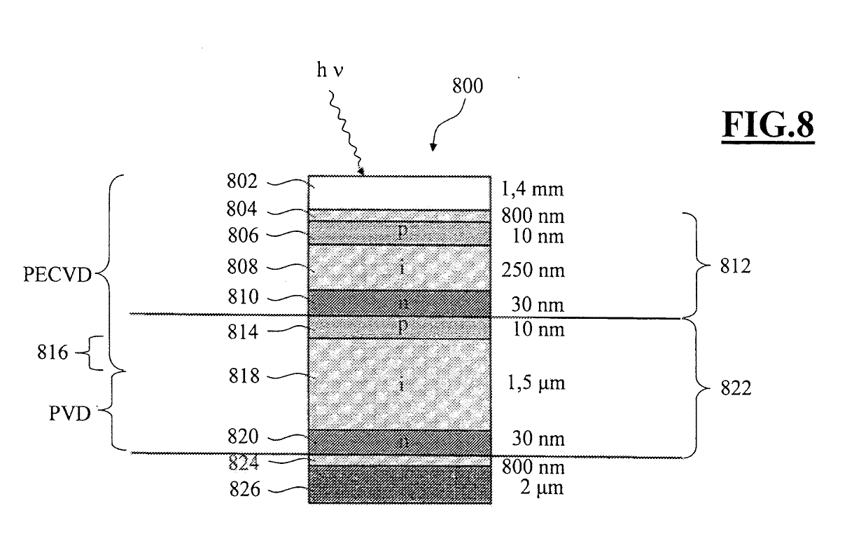

An apparatus of the type described above can be used to produce the crystalline silicon solar cell of an a-Si:H/μc-Si tandem solar cell with for example the structure illustrated in FIG. 8 in a manner not true to scale. The tandem cell 800 illustrated in FIG. 8 includes a sunlight-side (hv) upper a-Si:H solar cell 812 and a rear lower crystalline silicon solar cell 822. The a-Si:H cell 812 is directly adjacent to a transparent substrate composed of borosilicate glass 802 for example. An 800 nm thick SnO₂ layer serves as front electrode. Adjacent to the layer is a pin structure 806, 808, 810 having layer thicknesses of approximately 10 nm, 250 nm and 30 nm. Instead of a pin layer sequence, the a-Si-H cell can also have a pn structure. The rear solar cell 822 composed of crystalline silicon likewise in a pin structure is directly adjacent to the 30 nm thick n-conducting layer 810 of the a-Si:H solar cell 812. Typical thicknesses of the p-, i- and n-type layers are 10 nm, 1.5 μm and 30 nm. The back electrode is formed by a layer sequence ZnO: Al, Ag/Al having layer thicknesses of 800 nm and 2 μm. Given high crystallinity and a lower grain boundary density, a pn instead of pin structure of the μc-Si cell is also possible.

The a-Si:H solar cell 812 can be produced for example as follows: firstly the transparent electrode 804 is applied to the glass substrate 802 having a customary layer thickness of 1.4 mm, e.g. with the aid of a cathode sputtering method. The 10 nm thick and highly p-doped emitter layer is then applied, optionally by a PECVD method. The same method can also be used to deposit the approximately 250 nm thick intrinsic a-Si:H layer 808 and afterwards the n-doped collector layer 810 having a thickness of 30 nm. Corresponding coating installations are known in a multiplicity of modifications from the prior art and are not the subject matter of the present disclosure. An installation of this type can be disposed upstream on the input side of the continuous coating installations 100, 200, 300, 400, 500, 700 depicted schematically and described above, directly via a lock system.

There are various possibilities for producing the second solar cell 822—based on crystalline material—of the tandem structure 800 in a manner by PVD deposition of an amorphous silicon layer and subsequent laser crystallization of the layer.

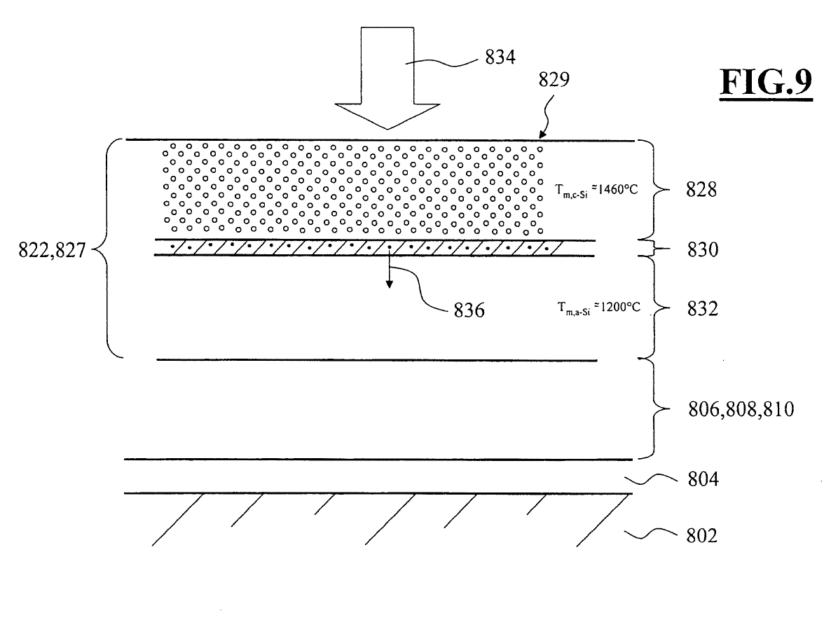

A first method example is explained below with reference to FIG. 9 of the drawing. FIG. 9 shows the layer construction after completion of the hydrogen-passivated amorphous silicon solar cell 812 (layer sequence: TCO 804, p-Si 806, i-Si 808, n-Si 810 on glass 802) with the aid of a PECVD method and after deposition of a further amorphous silicon layer 827 onto the finished a-Si:H solar cell with the aid of a high-rate PVD method, such as e.g. electron beam evaporation or sputtering.

In a first variant it is assumed that the amorphous silicon layer 827 has a layer thickness corresponding to the total layer thickness of the PIN structure of the crystalline silicon solar cell, that is to say approximately 1.5 μm. In the region of the n-doped a-Si layer 810, the amorphous silicon layer 827 can already have p-doping impurity atoms such as e.g. boron which were concomitantly deposited during the deposition of the a-Si layer by high-rate PVD methods from additional effusion cells (cf. explanations concerning FIGS. 1 and 2) . In a corresponding manner, n-doping atoms, such as e.g. phosphorus, may have been added during the deposition of the upper layer sheets. It is also possible, but not cost-effective, to carry out the corresponding doping of the last n-type layer subsequently with the aid of an ion implantation method. The corresponding regions of the amorphous silicon layer 827, after the crystallization thereof, are intended to form the p-and n-conducting zones of the crystalline solar cell 822.

The disclosure provides for areally illuminating the surface of this a-Si layer 827 produced by PVD with a laser beam 834 having a comparatively low fluence. In this case, the fluence of the laser is chosen in such a way that only that the upper layer sheets of the a-Si layer 827 melt. During the cooling down of the upper layer sheets, depending on the cooling rate and supercooling of the melt, a crystallization takes place to form fine-grained nanocrystallline silicon 828 (nc-Si). The crystallization heat of the phase transformation which is liberated during the crystallization process at the interface of nanocrystallline silicon 828/melt 830 is dissipated via the phase boundary of melt 830/a-Si 832. Since the melting point T_{m:C}-Si of crystalline silicon is approximately 1460° C. and is therefore higher than the melting point T_{m,a}-Si of amorphous silicon, which is only approximately 1200° C., the amorphous silicon situated at the phase boundary of melt 830/a-Si 832 is melted further depending on the temperature. The consequence is a progression of the melting zone 830 from the illuminated surface 829 in the direction of the a-Si cell 812. The fluence and duration of action of the laser beam 834 and the wavelength thereof, which determines the absorption length and thus the temperature profile, are advantageously chosen in such a way that the melting zone 830 progresses precisely as far as the interface with the amorphous silicon cell 812. When using a long-wave 532 nm laser, typical laser fluencies are 100-1500 mJ/cm² given a-Si layer thicknesses of <<100-1500 nm. In general it is expedient for the amorphous silicon layer that is to be melted to be heated to temperatures near the melting point thermally or in laser-induced fashion. Furthermore, the change from PECVD to PVD coating can also take place after the thin p-type layer 814.

In a second variant it is assumed that the amorphous silicon layer 827 has a layer thickness corresponding only to a fraction, e.g. 20 nm to 100 nm, of the total layer thickness of the pin structure of the silicon solar cell. By correspondingly applying the method described in the previous paragraph, it is possible to produce a seed layer for preventing spontaneous nucleation with many competing crystallites and grain boundaries or a buffer layer for limiting the progression of the melting front into the PECVD a-Si cell. The rest of the layer thickness involved for forming a c-Si solar cell can be deposited onto the seed layer by the same deposition and laser crystallization method or another method, in particular one of the methods described below. It is self-evident to the person skilled in the art that the method described above can also be applied repeatedly in each case after the deposition of a layer with a suitable layer thickness.

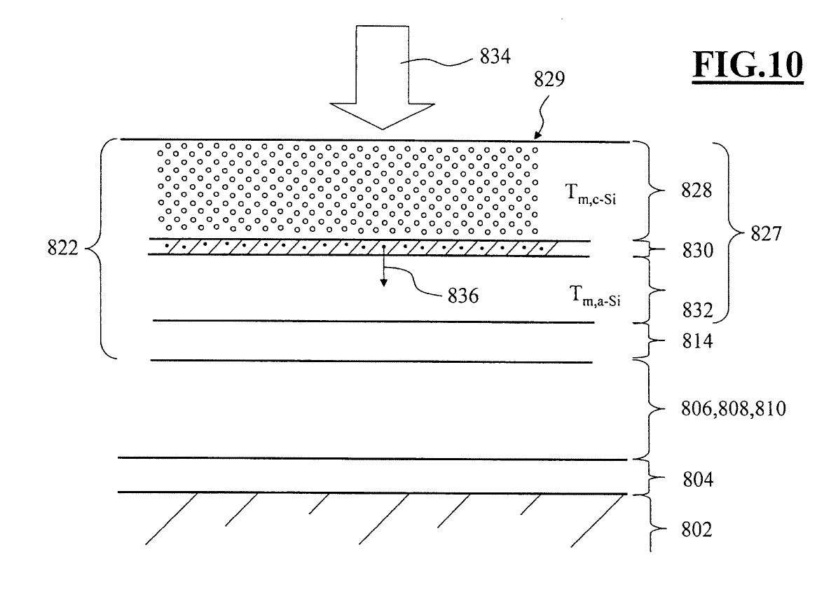

A second method example is described below with reference to FIG. 10 of the drawing. FIG. 10 shows the layer construction after the production of the hydrogen-passivated amorphous silicon solar cell 812 (layer sequence: TCO 804, p-Si 806, i-Si 808, n-Si 810 on glass 802) by PECVD methods (or some other suitable method) and after the deposition of a buffer layer 814 composed of nanocrystalline silicon. The nc-Si layer 814 can be produced in the same coating installation as and by a similar process to the individual layers 806, 808, 810 of the a-Si:H solar cell 812. If individual layers produced with the aid of PECVD are assumed, then it is advantageous also to produce the buffer layer with the aid of a PECVD process. The possible process parameters for producing an nc-Si layer by PECVD are sufficiently known from the literature.

The thickness of the buffer layer is chosen such that on the one hand, during subsequent process steps, the underlying a-Si cell 812 is not destroyed and, on the other hand, the total process duration is minimized. In the exemplary embodiment according to FIG. 10, the buffer layer 814 is chosen in terms of doping and thickness precisely such that, in the completed tandem structure 800, it corresponds precisely to the p-type layer 814 of the pin-c-Si solar cell 822.

As in the exemplary embodiment according to FIG. 9, an a-Si layer 827 is then applied to the buffer layer 814 at a high deposition rate by a PVD process such as e.g. cathode sputtering. The PVD a-Si layer 827 is subsequently illuminated over the whole area by a laser beam 834 having a low fluence, in the manner described in the above sections concerning FIG. 9 of the drawing. A melting zone 830 that propagates from the surface 829 to the buffer layer 814 forms with the formation of a fine-grained nanocrystallline film. The advantage of this variant is that the buffer layer 814 serves as a barrier for the further propagation—which is possible depending on the temperature profile—of the melting zone 830 since the melting point of the crystalline layer is again more than 200 K above that of the amorphous silicon layer. A mixing of the layers at the interface of buffer layer 814 and a-Si 832 practically does not take place provided that the PECVD nc-Si layer 814 lying at the bottom has a sufficient degree of crystallization.

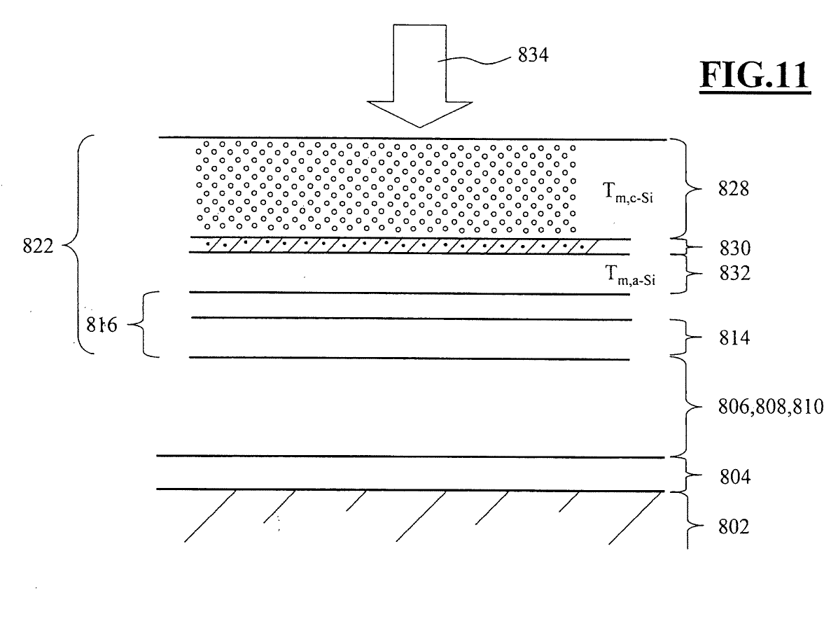

Experimental investigations have shown that the PECVD process for producing the p-doped nc-Si layer 814 involves a very precise process control in order to keep the portion of amorphous material in the matrix of the nc-Si layer 814 sufficiently small and in order to prevent a phase mixing from occurring in the interface region if the melting zone 830 meets the buffer layer 814. This is applicable all the more since the fluence and duration of action of the laser beam 834 have to be chosen to be large enough to ensure complete crystallization through the a-Si layer 832 even if the deposition rate of silicon is subject to certain fluctuations during the PVD process. In a third method example, therefore, in order to increase the process tolerance, provision is made for depositing not only the p-Si layer 814 by PECVD, but furthermore a number of nanometres, if appropriate tens of nanometres, of undoped nc-silicon. An intermixing of i- and p-type zones in subsequent process steps is then efficiently prevented. FIG. 11 shows this case in comparison with the method according to FIG. 10. The thicker PECVD nc-Si layer is identified by the reference symbol 816 in the figure of the drawing.

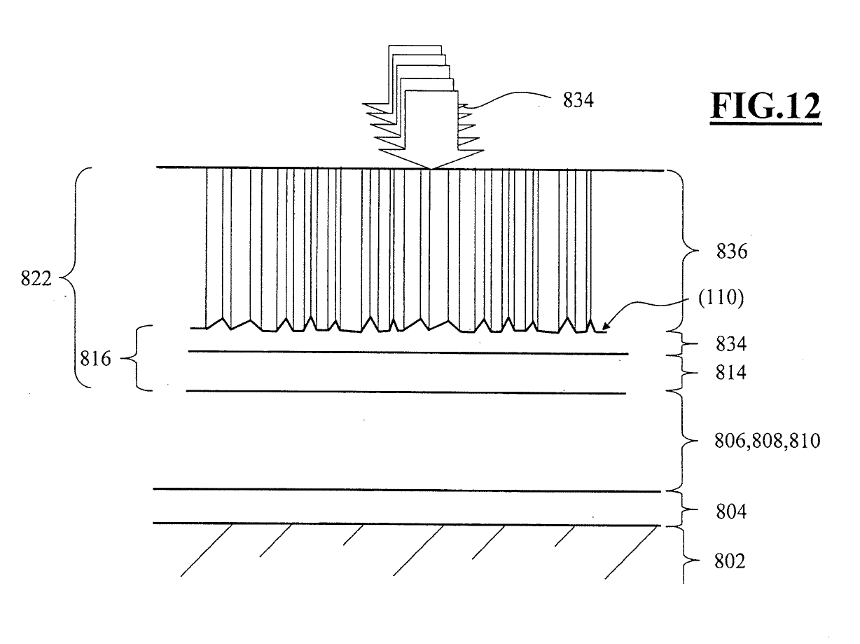

A fourth method example is explained below with reference to FIG. 12 of the drawing. FIG. 12 likewise shows the layer construction after the completion of the hydrogen-passivated amorphous silicon solar cell 812 (layer sequence: TCO 804, p-Si 806, i-Si 808, n-Si 810 on glass 802) and after the deposition of a buffer layer 816 of the type used in the exemplary embodiment described above, namely a crystalline p-Si layer 814 and a thin crystalline i-Si layer 834.

In a departure from the above exemplary embodiment, the i-Si layer is not as fine-grained. By correspondingly varying the SiH₄: H ratio during the PECVD process for depositing the i-Si layer, it is possible to produce crystallites having diameters of a few tens of nanometres, optionally with a (110) surface normal texture. This is followed by the deposition of an amorphous silicon film of e.g. approximately 50-100 nm thickness with the aid of a high-rate PVD method such as e.g. electron beam evaporation or sputtering and subsequent laser crystallization with high laser energy that melts the entire a-Si layer thickness, such that an epitaxial crystal layer forms during subsequent cooling down. This procedure of deposition of an e.g. 100 nm thick a-Si layer and subsequent complete melting (referred to as: “complete melting regime”) by laser illumination 834 is repeated until the desired final thickness of the layer 836 is reached. Longer cooling times of the melt and thus higher layer thicknesses per crystallization step are possible with a higher laser fluence, longer pulse duration and/or longer-wave lasers.

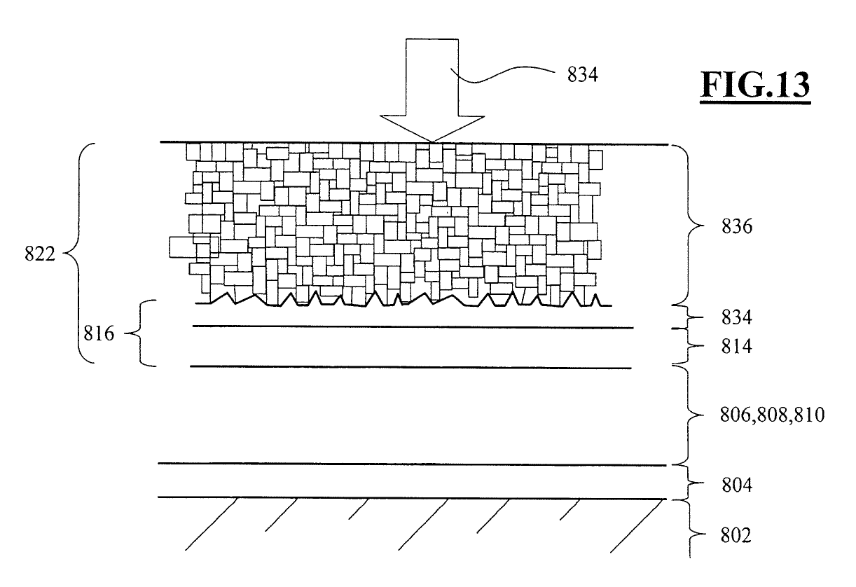

Instead of an epitaxial layer growth, a non-epitaxial layer growth can also produce a crystalline layer having sufficient layer quality. Thus, e.g. the method described in association with FIGS. 9 to 11 with the independently propagating melting zone (referred to as “self-propagating liquid layer”, low laser fluence, long-wave laser, heat pretreatment) can yield sufficiently good results. As a further non-epitaxial method it is possible to use the so-called “partial melting” method, in which the PVD-deposited layer is only partially melted over its thickness and a spontaneous crystallization commences to form very small nanocrystallites. A method related to this is the likewise possible “nucleation regime”, in which a crystallization takes place at specially added nucleation centres. In the two methods mentioned last, it is not necessary for the seed layer 834 to have particularly large crystallites. Therefore, a particular adaptation of the H concentration to the SiH₄ concentration in order to increase the crystallite size is not necessary. FIG. 13 shows in summary the layer structure in accordance with FIG. 12 but with non-epitaxial growth of the upper layer 836.

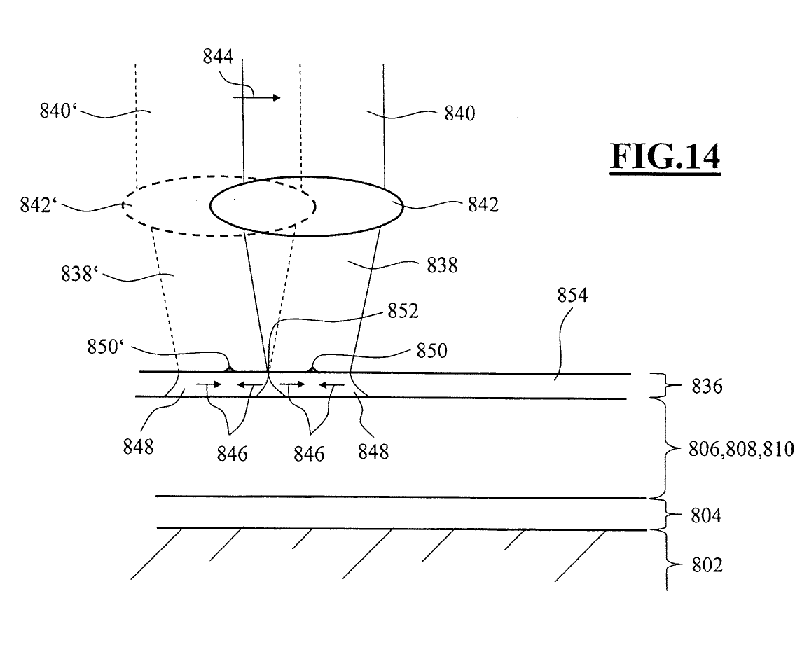

A sixth method example will now be explained with reference to FIG. 14. The latter shows the layer construction of the tandem solar cell 800 to be produced after the completion of the hydrogen-passivated amorphous silicon solar cell 812 (layer sequence: TCO 804, p-Si 806, i-Si 808, n-Si 810 on glass 802) and after the deposition of a thin amorphous silicon layer 836 of approximately 50 nm to 100 nm by a PVD method such as cathode sputtering or electron beam evaporation. The silicon layer 836 is crystallized by the SLS method mentioned in the introduction to the description. The method involves guiding in pulsating fashion a linear illumination line 838′, 838 having a width of up to a few tens of micrometres and a length of a number of decimetres over the surface of the layer 854 to be crystallized. In concrete terms, each temporally directly succeeding laser pulse 838 produces an illumination line on the surface of the layer 854 which is shifted from the illumination line of the temporally directly preceding laser pulse 838′ by the width of the illumination line 838′, 838. FIG. 14 shows the beam path of two directly temporally successive laser pulses 840′, 840 through a focusing lens 842′, 842. The direction of movement of the lens 842, 842′ is indicated in FIG. 14 by an arrow provided with the reference symbol 844.

Each laser pulse 838′, 838 melts the amorphous silicon layer at the respective impingement location over the entire thickness of the film (“complete melting regime”). In the course of cooling down, the melted material solidifies and crystallizes from the respective edges. The crystallization direction is identified by arrows 846 in the drawing. The crystallites 848′, 848 that meet one another in the centre of the line width form grain boundaries 850′, 850 which are elevated in the direction of the layer surface normal. The elongate e.g. 3 μm long crystallites which arise during this method have dimensions of approximately half the illumination line width given a width of hundreds of nanometres.

If the method is subsequently carried out once again transversely with respect to the direction 844, then crystallites of approximately 3 μm×3 μm result. This method is referred to in the literature as SLS² method. After the production of a first layer with large crystallites, further epitaxial layer growth is also possible using the ELA method in the “complete melting regime”.

Layer deposition and subsequent laser crystallization using the ELA, SLS or SLS² method are effected repeatedly until the desired final thickness of approximately 1.5 μm is reached.

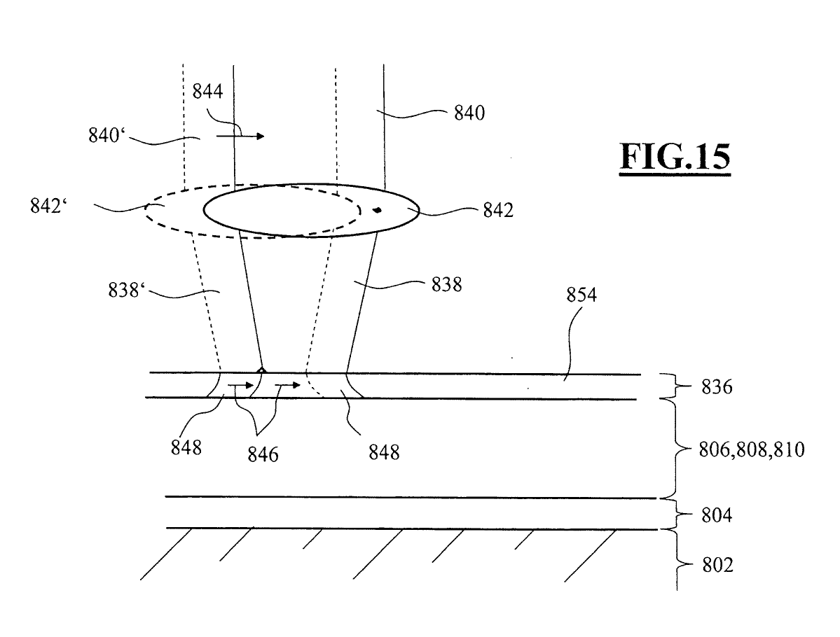

A seventh method example is explained below with reference to FIG. 15. FIG. 15 shows the layer construction of the tandem solar cell 800 to be produced after the completion of the hydrogen-passivated amorphous silicon solar cell 812 (layer sequence: TCO 804, p-Si 806, i-Si 808, n-Si 810 on glass 802) and after the deposition of a thin amorphous silicon layer 836 of approximately 50 nm to 100 nm by a PVD method such as cathode sputtering or electron beam evaporation.

Instead of the SLS method outlined schematically in FIG. 14, FIG. 15 shows the so-called TDX™ method. This method, in a similar manner to the SLS method, involves guiding in pulsating fashion a linear illumination line 838′, 838 having a width of a few micrometres and a length of a number of decimetres over the surface of the layer 854 to be crystallized. In a departure from the SLS method, each temporally directly succeeding laser pulse 838 produces an illumination line on the surface of the layer 854 which is shifted from the illumination line of the temporally directly preceding laser pulse 838′ by less than half the width of the illumination line 838′, 838. FIG. 15 shows the beam path of two directly temporally successive laser pulses 840′, 840 through a focusing lens 842′, 842. The direction of movement of the lens 842, 842′ is indicated in FIG. 15 by an arrow provided with the reference symbol 844.

Each laser pulse 838′, 838 melts the amorphous silicon layer and the corresponding layer which has already been crystallized by the temporally preceding laser pulse at the respective impingement location over the entire thickness of the film (“complete melting regime”). In the course of cooling down the melted material solidifies and crystallizes again from the respective edges. Since the crystallized end layer is formed from partial layers which are crystallized in direction 846 of the direction 844 of movement of the laser beam 838′, 838, very long crystallites form in the lateral direction. The crystallites which arise during this method have dimensions of tens to hundreds of micrometres given a width of hundreds of nanometres.

If the method is subsequently carried out once again transversely with respect to the direction 844, then crystallites of approximately 10×10 μm to 100×100 μm result. This method is called the TDX² method. As in the SLS² method, the further layer growth can be effected by laser crystallization by ELA, i.e. vertical crystallization, or by SLS or TDX, i.e. lateral crystallization, until the desired final thickness of approximately 1.5 μm is reached.

All of the layers produced by the methods described above can be subjected to a hydrogen passivation after the laser crystallization.

The n-type layer 820 is produced by evaporation of phosphorus by an effusion cell and geometrical partitioning for delimiting the coating region to a width of a few cm in the feedthrough direction and subsequent laser crystallization (cf. FIG. 1).

A transparent electrode is in turn deposited onto this n-conducting layer. In the present exemplary embodiment, aluminium-doped zinc oxide 824 is sputtered on. The metallic rear area contact composed of Ag/Al is applied for example by electron beam evaporation.

### LIST OF REFERENCE SYMBOLS

100 Continuous coating installation

102 Supply opening

104 Discharge opening

106 Substrate

108 Substrate holder with transport rollers

110 Vacuum chamber

112 Electron beam evaporation device

114 Electron beam

116 Evaporator crucible

118 Silicon

120 Directed vapour jet

122 Laser crystallization (illumination) system

124 Laser beam

126 Surface of the substrate 128 Chamber window

130 Currently coated partial area

132 Currently illuminated sub-partial area, laser beam profile

134 Already coated partial area

136 Feedthrough direction

138 Effusion cell

140 Gap

142 Vapour jet

144 Effusion cell

146 Gap

148 Vapourjet

200 Continuous coating installation

202 Laser

204 Laser

206 Laser

208 Two-dimensional single-stage homogenizer

210 Two-dimensional single-stage homogenizer

212 Two-dimensional single-stage homogenizer

214 Quad prism

216 Quad prism

218 Quad prism

220 Pupil plane

222 Pupil plane

224 Pupil plane

226 Field plane

228 Two-dimensional galvo-scanner

230 Galvo-mirror

232 Galvo-mirror

234 Rotation axis

236 Rotation axis

238 Scanning objective

240 Laser beam

242 Laser beam

244 First scanning direction

246 Second scanning direction

248 Field

250 Field

252 Field

254 Laser beam

256 Laser beam

258 Laser beam

260 Homogenized laser beam

262 Homogenized laser beam

262 Homogenized laser beam

264 Subdivided laser beam

266 Subdivided laser beam

268 Subdivided laser beam

270 Subdivided laser beam

272 Laser beam imaged in field plane

274 Laser beam imaged in field plane

276 Laser beam imaged in field plane

278 Laser beam imaged in field plane

300 Continuous coating installation

302 Laser

304 Laser

306 Laser

308 Laser beam

310 Laser beam

312 Laser beam

314 Two-dimensional single-stage homogenizer

316 Roof prism

318 Pupil plane

320 Field plane

322 Homogenized laser beam

324 Subdivided and deflected laser beam

326 Subdivided and deflected laser beam

328 One-dimensional galvo-scanner

330 One-dimensional galvo-scanner

332 Scanning objective

334 Scanning objective

336 Scanning direction of the galvo-scanner

338 Scanning direction of the galvo-scanner

340 Field

342 Field

344 Field

346 Scanning direction of the substrate holder

400 Continuous coating installation

402 Laser

404 Laser

406 Laser

408 Laser beam

410 Laser beam

412 Laser beam

414 Two-dimensional two-stage homogenizer

416 Homogenized laser beam

418 Roof prism

420 Pupil plane

422 Field plane

424 Anamorphic objective

426 Anamorphic objective

428 Subdivided and deflected laser beam

430 Subdivided and deflected laser beam

432 Laser beam expanded in one direction and focused in one direction

434 Laser beam expanded in one direction and focused in one direction

436 Cylindrical lens

438 Cylindrical lens

440 Cylindrical lens

442 Cylindrical lens

444 Illumination line with short and long axis

446 Illumination line with short and long axis

448 Scanning direction of the substrate holder

500 Continuous coating installation

502 Laser

504 Laser

506 Laser

508 Laser beam

510 Laser beam

512 Laser beam

514 Two-dimensional two-stage homogenizer

516 Two-dimensional two-stage homogenizer

518 Two-dimensional two-stage homogenizer

520 Reflector

522 Reflector

524 Reflector

526 Cylindrical lens arrangement

528 Line foci

530 Field plane

532 Laser beam

534 Laser beam

536 Laser beam

700 Continuous coating installation

702 Laser

704 Laser

706 Laser beam

708 Laser beam

710 Homogenizer

712 Homogenizer

714 Scanning mirror

716 Scanning mirror

718 Homogenized laser beam

720 Homogenized laser beam

722 Scanning direction

724 Scanning direction

726 Laser beam

728 Laser beam

800 Tandem solar cell

802 Glass substrate

804 Transparent electrode (SnO₂)

806 a-Si (p-doped)

808 a-Si (undoped)

810 a-Si (n-doped)

812 a-Si solar cell (top cell)

814 μc-Si (p-doped)

816 Seed layer

818 μc-Si (undoped)

820 μc-Si (n-doped)

822 μc-Si solar cell (bottom cell)

824 Transparent electrode (ZnO₂: Al)

826 Metal back electrode (Ag/Al)

828 Nanocrystalline silicon

830 Melting zone

832 a-Si

834 Laser beam

836 Thin amorphous silicon layers

838 Linear illumination line

840 Laser pulse

842 Lens

844 Direction of movement

846 Direction of movement

848 Crystallites that meet one another

b Substrate width

1 Substrate length

hv Light energy

What is claimed is:

1. An installation, comprising:
a vacuum chamber having a supply opening configured to supply a substrate to be coated and a discharge opening configured to discharge the substrate after a surface of the substrate is coated;
a physical vapour deposition device configured to coat the surface of the substrate;
a laser crystallization system configured to expose a portion of the surface of the substrate to a laser beam so that the portion of the surface of the substrate can be coated via the physical vapour deposition device while the portion of the substrate is exposed to the laser beam; and
a transport device configured to transport the substrate in a feedthrough direction from the supply opening to the discharge opening,
wherein the installation is configured so that the substrate can move continuously from the supply opening to the discharge opening while the surface of the substrate is being coated via the physical vapour deposition device.

2. The installation according to claim 1, wherein the physical vapour deposition device comprises an electron beam evaporation device or a cathode sputtering device.

3. The installation according to claim 1, wherein:
the physical vapour deposition device comprises a plurality of electron beam evaporation devices arranged alongside one another perpendicular to the feedthrough direction; and/or
the physical vapour deposition device comprises a plurality of cathode sputtering devices arranged alongside one another perpendicular to the feedthrough direction.

4. The installation according to claim 1, wherein the transport device comprises a movement device configured to move the substrate in a direction perpendicular to the feedthrough direction.

5. The installation according to claim 1, wherein the laser crystallization system is rigid.

6. The installation according to claim 1, wherein the laser crystallization system comprises a laser beam movement device that can be moved to guide the laser beam over the portion of the substrate independently of the movement of the substrate.

7. The installation according to claim 6, wherein the laser beam movement device can be moved in two directions that are perpendicular to one another.

8. The installation according to claim 6, further comprising a linear motor configured to linearly move the laser beam movement device.

9. The installation according to claim 6, wherein the laser beam movement device has a mirror configured to deflect the laser beam onto the portion of the substrate.

10. The installation according to claim 1, wherein the laser crystallization system comprises a first laser angle scanner that can be pivoted about a first axis to direct the laser beam onto the substrate from different directions.

11. The installation according to claim 10, wherein the first laser angle scanner can be pivoted about a second axis different from the first axis.

12. The installation according to claim 10, wherein the laser crystallization system further comprises a second laser angle scanner that can be pivoted about a second axis to direct the laser beam onto the first laser angle scanner.

13. The installation according to claim 10, further comprising an imaging objective to image the laser beam onto the portion of the substrate so that a contour and size of the laser beam on the portion of the substrate remain essentially unchanged if the laser beam is directed onto the substrate from different directions.

14. The installation according to claim 12, wherein the first laser angle scanner and/or the second laser angle scanner comprises a galvo-mirror to deflect the laser beam in a different manner.

15. The installation according to claim 1, further comprising a multiplex device configured to generate a plurality of laser beams to simultaneously illuminate a plurality of portions of the substrate.

16. The installation according to claim 1, further comprising:
a deposition measuring device configured to measure a deposition rate and/or a deposition quantity of a material deposited on the surface of the substrate via the vapour deposition device; and
a device configured to provide open-loop and/or closed-loop control, respectively, of a location of the portion of the substrate and/or a current intensity of the laser beam on the substrate depending on the measured deposition rate and/or the measured deposition quantity.

17. The installation according to claim 1, further comprising:
a device configured to measure a layer thickness change and/or a layer thickness of the layer deposited on the surface of the substrate; and
a device configured to provide open-loop and/or closed-loop control, respectively, of a location of the portion of the substrate and/or a current intensity of the laser beam on the substrate depending on the measured layer thickness change and/or the measured layer thickness.

18. The installation according to claim 1, further comprising a mirror configured to reflect a portion of the laser beam reflected from the portion of the substrate back onto the portion of the substrate or an area containing the portion of the substrate.

19. A method, comprising:
while moving a substrate through a vacuum chamber, using physical vapour deposition to form a layer of material on a portion of a surface of the substrate and simultaneously exposing the material on the portion of the substrate to a laser beam to crystallize the material on the portion of the substrate to produce a nano-, micro-, poly-, multi- or monocrystalline thin film of the material.

20. An article, comprising:
a first solar cell, the first solar cell comprising amorphous silicon; and
a second solar cell, the second solar cell comprising crystalline silicon,
wherein the first and second solar cells are arranged monolithically one above another, and the second solar cell comprises a silicon layer having crystallites with grain diameters of between 20 nm and 5 μm, and the article is a tandem solar cell.
